(19) United States
(12) Patent Application Publication
(10) Pub. No.: US 2013/0062643 A1
(43) Pub. Date: Mar. 14, 2013

(54) LIGHT EMITTING DEVICE

(71) Applicant: Tetsuya MURANAKA, Fukuoka-ken (JP)

(72) Inventor: Tetsuya MURANAKA, Fukuoka-ken (JP)

(73) Assignee: Kabushiki Kaisha Toshiba, Tokyo (JP)

(21) Appl. No.: 13/422,490

(22) Filed: Mar. 16, 2012

(30) Foreign Application Priority Data
Sep. 13, 2011 (JP) 2011-199047

(51) Int. Cl. H01L 33/36

(52) U.S. Cl. 257/98; 257/E33.062

(57) ABSTRACT

According to one embodiment, a light emitting device includes: a first lead, a recess being provided in the first lead; a light emitting element fixed to a bottom surface of the recess via a conductive paste at a back surface on an opposite side to a light emitting surface of the light emitting element; and a second lead disposed away from the first lead and electrically connected to the light emitting element via a metal wire. An area of the bottom surface is larger than an area of the light emitting surface. The paste is put in with a thickness sufficient to cover at least part of a side surface in contact with the light emitting surface and the back surface of the light emitting element and at least part of a wall surface of the recess in the recess.

### CROSS-REFERENCE TO RELATED APPLICATIONS

This application is based upon and claims the benefit of priority from the prior Japanese Patent Application No. 2011-199047, filed on Sep. 13, 2011; the entire contents of which are incorporated herein by reference.

### FIELD

Embodiments described herein relate generally to a light emitting device.

### BACKGROUND

High light output and high reliability are required for light emitting devices. There is, for example, a light emitting device in which an LED (light emitting diode), which is a semiconductor light emitting element, is fixed to a lead frame and sealed with a resin. In this type of light emitting device, it is important to diffuse the heat of the LED with good efficiency via the lead frame in order to improve light emitting efficiency. Furthermore, it is necessary to increase the fixing strength of the LED to the lead frame in order to improve reliability. On the other hand, to simplify the manufacturing processes of the light emitting device to reduce costs, for example, a method is widely used in which a conductive paste is used to fix the light emitting element to the lead frame.

However, the conductive paste has a small thermal conductivity and a weak adhesive strength as compared to metal solders. Hence, decreases in light emitting efficiency and reliability may be caused in the device in which the conductive paste is used to fix the light emitting element. Therefore, a light emitting device is required in which the conductive paste is used to fix the light emitting element to the lead frame and the light emitting efficiency and reliability can be improved.

### BRIEF DESCRIPTION OF THE DRAWINGS

FIGS. 1A and 1B are schematic views showing a light emitting device according to a first embodiment;

FIGS. 2A and 2B are schematic views schematically showing a mount unit for the light emitting element in the light emitting device according to the first embodiment;

FIGS. 3A and 3B are schematic views showing the mount structure of the light emitting element in light emitting devices according to modification examples of the first embodiment;

FIG. 4A and FIG. 4B are cross-sectional views schematically showing light emitting devices according to modification examples of the first embodiment;

FIG. 5 is a graph showing the light output characteristics of the light emitting device according to the first embodiment;

FIG. 6 shows the change in the total luminous flux with respect to a thickness of the conductive paste in the light emitting device according to the first embodiment;

FIGS. 7A and 7B are cross-sectional views schematically showing the mount structures of light emitting elements according to a second embodiment;

FIGS. 8A and 8B are schematic views showing a light emitting device according to a third embodiment;

FIGS. 9A to 9C are a graph and photographs showing the light distribution characteristics of the light emitting device according to the third embodiment;

FIG. 10 is a graph showing the luminous flux utilization rates of the light emitting device according to the third embodiment; and

FIG. 11 is a schematic diagram showing a mount structure of light emitting elements according to a comparative example.

### DETAILED DESCRIPTION

In general, according to one embodiment, a light emitting device includes: a first lead, a recess being provided in the first lead; a light emitting element fixed to a bottom surface of the recess via a conductive paste at a back surface on an opposite side to a light emitting surface of the light emitting element; and a second lead disposed away from the first lead and electrically connected to the light emitting element via a metal wire. An area of the bottom surface is larger than an area of the light emitting surface. The paste is put in with a thickness sufficient to cover at least part of a side surface and at least a part of a wall surface of the recess in the recess. The side surface is in contact with the light emitting surface and the back surface of the light emitting element.

In general, according to another embodiment, a light emitting device includes: a first lead; a light emitting element fixed to the first lead; and a second lead disposed away from the first lead and electrically connected to the light emitting element via a metal wire. The light emitting element is fixed to the first lead via a conductive paste at a back surface on an opposite side to a light emitting surface. The metal wire is bonded to the light emitting surface. The paste covers a portion larger than ½ of a thickness of the light emitting element from the back surface of a side surface in contact with the light emitting surface and the back surface of the light emitting element.

Hereinbelow, embodiments of the invention are described with reference to the drawings. Identical components in the drawings are marked with the same reference numerals, and a detailed description thereof is omitted as appropriate and different components are described.

### First Embodiment

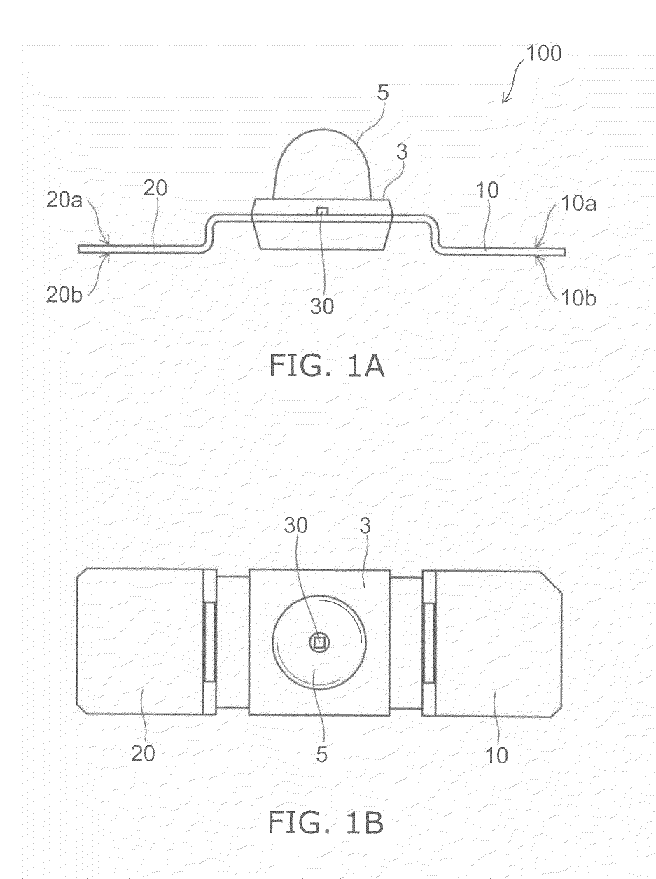

FIGS. 1A and 1B are schematic views showing a light emitting device 100 according to a first embodiment. FIG. 1A is a front view, and FIG. 1B is a plan view. The light emitting device 100 has a configuration in which an LED, for example, is fixed to the front surface of a lead frame and is sealed by a resin molded body as one body.

As shown in FIG. 1A and FIG. 1B, the light emitting device 100 includes a lead 10 that is a first lead and a lead 20 that is a second lead. A light emitting element 30 is fixed to the front surface of the lead 10. The lead 20 is disposed away from the lead 10 in such a manner that an end of the lead 20 is opposed to an end of the lead 10.

The lead 20 is electrically connected to the light emitting element 30 via a metal wire. Thereby, a current can be supplied between the lead 10 and the lead 20 to cause the light emitting element 30 to emit light.

A molded body 3 is provided to cover the ends of the lead 10 and the lead 20 where the lead 10 and the lead 20 are opposed to each other. The molded body 3 is molded by, for example, the injection molding of a transparent resin. The molded body 3 resin-seals the light emitting element 30 fixed to the lead 10 and the metal wire, and shields them from the outside. The transparent resin transmits the light that the light emitting element 30 emits, and allows light to be emitted to the outside. The transparent resin preferably transmits all the light that the light emitting element 30 emits and allows it to be emitted to the outside, but may absorb part of it.

A lens 5 for condensing the light emitted from the light emitting element 30 is provided on the molded body 3. The lens 5 is provided on the side of the front surface 10a of the lead 10 to which the light emitting element 30 is fixed, and may be, for example, molded as one body together with the molded body 3.

As shown in FIG. 1A, portions extending from the molded body 3 of the lead 10 and the lead 20 are processed by bending. Thereby, the back surface 10b of the lead 10 and the back surface 20b of the lead 20 can be, for example, mounted in contact with circuit interconnections.

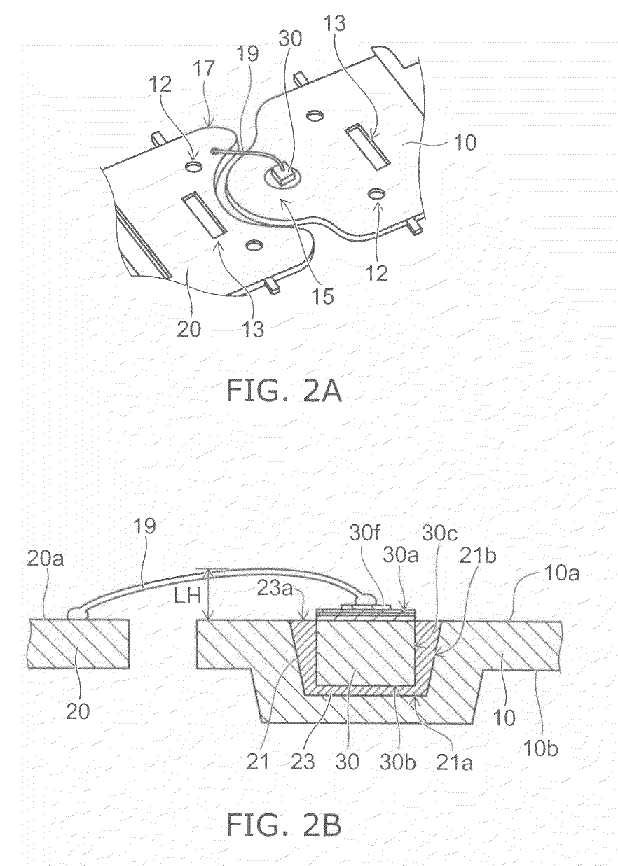

FIGS. 2A and 2B are schematic views schematically showing a mount unit 15 for the light emitting element 30 in the light emitting device 100. FIG. 2A is a schematic view showing the mount unit 15 excluding the molded body 3, and FIG. 2B is a cross-sectional view thereof.

As shown in FIG. 2A, the mount unit 15 for the light emitting element 30 is provided at the end of the lead 10. A metal wire 19 electrically connecting the light emitting element 30 and the end of the lead 20 is bonded.

Anchor holes 12 and 13 are provided in end portions of the leads 10 and 20 covered with the molded body 3. The anchor holes 12 and 13 connect the resins molded on the front surface side and the back surface side of the leads, and engage the molded body 3 with the leads. Thereby, the leads 10 and 20 are fixed to the molded body 3.

Further, as shown in FIG. 2B, a recess 21 is provided in the mount unit 15 for the light emitting element 30 in the lead 10. The recess 21 is formed in a larger size than the chip surface (light emitting surface) 30a of the light emitting element 30, and the light emitting element 30 is fixed to the bottom surface 21a of the recess 21. The recess 21 thus configured can be formed by, for example, pressing a copper alloy that is the material of the lead 10.

The light emitting element 30 is fixed to the bottom surface 21a of the recess 21 via a conductive paste 23 at the back surface 30b on the opposite side to the light emitting surface 30a of the light emitting element 30.

The conductive paste 23 is, for example, what is called an Ag paste in which fine particles of silver (Ag) are scattered in a resin having adhesive properties. The conductive paste 23 fixes the light emitting element 30 to the bottom surface 21a, and electrically connects the lead 10 and the light emitting element 30. The conductive paste 23 herein is not limited to an Ag paste but may be any adhesive material having an electrical conductivity after drying.

The area of recess 21 is set larger than the area of the light emitting surface 30a of the light emitting element 30. The conductive paste 23 is put in with a thickness sufficient to cover at least part of the side surface 30c of the light emitting element 30 fixed to the bottom surface 21a of the recess 21 and at least part of the wall surface 21b of the recess 21. The conductive paste 23 more preferably has a surface parallel to the bottom surface 21a between the light emitting element 30 and the wall surface 21b.

Here, “parallel” not only refers to strictly parallel states but also includes nearly parallel states and partly parallel states. The side surface 30c of the light emitting element 30 refers to the surface in contact with the light emitting surface 30a and the back surface 30b.

The conductive paste 23 contains a resin, and therefore, for example, has a higher adhesion to the transparent resin forming the molded body 3 than the front surface 10a of the lead 10 has. Therefore, by attaching the molded body 3 and the conductive paste 23 together between the light emitting element 30 and the wall surface 21b, the seal of the light emitting element 30 can be strengthen to improve the reliability thereof.

The light emitting element 30 includes, for example, a bonding pad 30f on the light emitting surface 30a thereof. As shown in FIG. 2B, the metal wire 19 is bonded between the bonding pad 30f and the front surface 20a of the lead 20 to electrically connect the lead 20 and the light emitting element 30. At this time, since the light emitting element 30 is sunk in and fixed to the recess 21, the height of the bonding pad 30f decreases to near the front surface 10a of the lead 10. Thereby, the looping L_{H} of the metal wire can be reduced, and for example, the deformation due to resin molding can be suppressed.

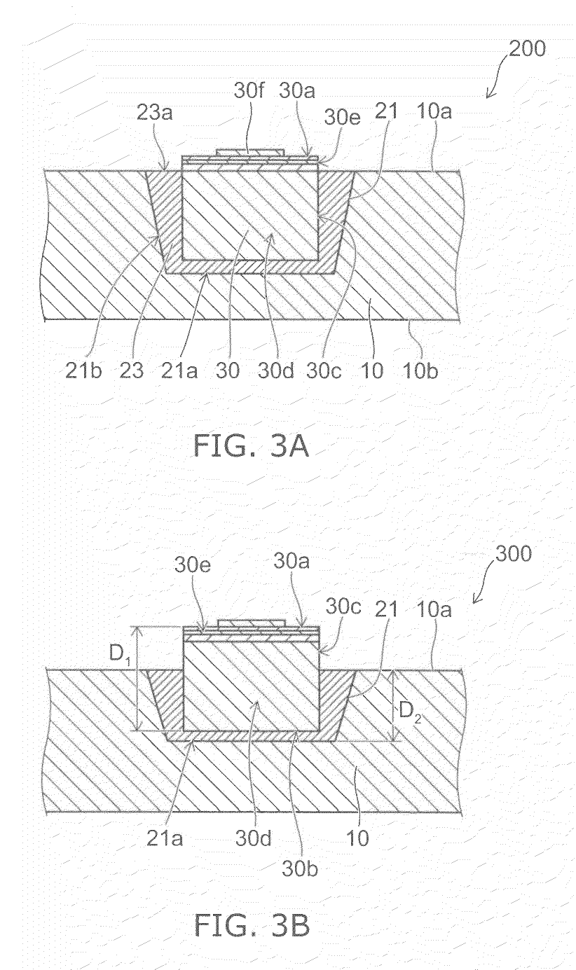

In the example shown in FIGS. 2A and 2B, for example, the size of the light emitting surface 30a is set to 350 μm×350 μm, and the chip thickness D₁ is set to 260 μm. Assuming that a clearance of 50 μm is provided for the outer periphery of the light emitting element 30, the size of the bottom surface of the recess 21 may be set to, for example, 450 μm×450 μm. The depth D₂ of the recess 21 is set to, for example, 200 μm (see FIG. 3B).

As shown in FIG. 2B, the conductive paste is put in almost the entire space of the interior of the recess 21 to which the light emitting element 30 is fixed. The thickness of the conductive paste interposed between the light emitting element 30 and the bottom surface 21a may be set not more than 10 μm; thereby, the light emitting element 30 sinks into the conductive paste 23 while approximately a 20% portion of the light emitting element 30 is protruded from the recess 21. Thereby, the fixing strength of the light emitting element 30 to the lead 10 can be increased. Furthermore, the heat generated in the light emitting element 30 can be diffused with good efficiency to the lead 10 via the conductive paste 23.

Further, for example, a configuration is preferable in which the depth of the recess 21 is set to 230 μm to 250 μm and the light emitting element 30 is sunk into the conductive paste 23 to a level such that approximately the upper 10% of the side surface 30c is left. Thereby, a state can be obtained in which the light emitting unit of the light emitting element 30 is protruded from the recess 21 and the most part of the substrate supporting the light emitting unit is covered with the conductive paste 23. Thus, the fixing strength and heat radiation of the light emitting element 30 can be further increased.

The conductive paste 23 may contain a metal that reflects the emission light of the light emitting element 30. Thereby, for example, the light emitted from the light emitting element 30 in the horizontal direction (a direction substantially parallel to the surface of the conductive paste 23) is reflected at the surface 23a of the conductive paste 23, and contributes to light output. That is, the light output of the light emitting device 100 is increased.

FIGS. 3A and 3B are schematic views showing the mount structure of the light emitting element 30 in light emitting devices 200 and 300 according to modification examples of the embodiment. In the lead 10 shown in the modification examples, the recess 21 is formed using, for example, the etching method. Therefore, the back surface 10b of the lead 10 is kept in a flat state.

As shown in FIG. 3A, a configuration is preferable in which the most part of a substrate 30d of the light emitting element 30 is covered with the conductive paste 23 and a light emitting unit 30e is protruded from the recess 21. On the other hand, as shown in FIG. 3B, a configuration is also possible in which the depth D₂ of the recess 21 is made shallow and part of the substrate 30d is covered with the conductive paste. However, to increase the fixing strength and heat radiation of the light emitting element 30, ½ or more of the side surface 30c is preferably covered with the conductive paste 23. For example, if it is assumed that the thickness of the conductive paste interposed between the back surface 30b of the light emitting element 30 and the bottom surface 21a of the recess 21 is negligibly thin (10 μm or less), the depth D₂ of the recess 21 is set to ½ or more of the chip thickness D₁ of the light emitting element 30.

Next, another aspect of the embodiment is described with reference to a light emitting device 900 according to a comparative example shown in FIG. 11. As shown in FIG. 11, the light emitting device 900 has a structure in which, on the back surface side of a light emitting element 40, the conductive paste 23 covers part of the side surface 40c. That is, on the side of the back surface 40b of the light emitting element 40, a fillet 23c lying along the outer periphery of the chip is formed, and the conductive paste covers part of the side surface 40c.

The light emitting element 40 is, for example, an LED in which a light emitting unit 40e is provided on a GaP substrate 40d. In the light emitting element 40, since the GaP substrate 40d transmits the light emitted from the light emitting unit 40e, light is emitted not only from the light emitting surface 40a but also from the chip side surface 40c. Therefore, if the area covered with the fillet 23c is increased in the chip side surface 40c, light may be blocked to reduce output. In view of this, the fillet 23c is provided such that the portion of the side surface 40c covered with the fillet 23c is, for example, not more than 20% of the entire side surface.

In contrast, what is called a thin-film type LED is widely used having a structure in which the light emitting unit is transferred onto a support substrate. In the thin-film type LED, a silicon substrate used as the support substrate absorbs the light that the light emitting unit emits. Therefore, a reflection electrode is interposed between the light emitting unit and the support substrate so that light may not be propagated to the support substrate side. That is, in the thin-film type LED, no light is emitted from the side surface of the support substrate.

For example, if the mount structure shown in FIG. 3A is used for the thin-film type LED, the most part of the side surface of the substrate 30d that is a silicon substrate is covered with the conductive paste. Thereby, the fixing strength and heat radiation to the lead 10 can be increased. Furthermore, since no light is emitted from the substrate 30d, the light output does not decrease. On the contrary, the silicon substrate (the substrate 30d) that forms a light absorber is covered with the conductive paste 23 that reflects light, and the light absorption at the substrate 30d can be suppressed, which increases output.

Thus, the mount structure of the light emitting element 30 according to the embodiment may be used for the thin-film type LED; thereby, the fixing strength to the lead 10 can be increased to improve reliability. Furthermore, the heat radiation from the light emitting element 30 can be increased to increase light emitting efficiency. In addition, by covering the support substrate with the conductive paste, light absorption can be suppressed to increase the light output directly.

Laser dicing, for example, may be used in chipping the light emitting element 30; thereby, unevenness can be provided at the side surface 30c. Thereby, the adhesion between the conductive paste 23 and the light emitting element 30 can be strengthened, and also the fixing strength and heat radiation can be increased.

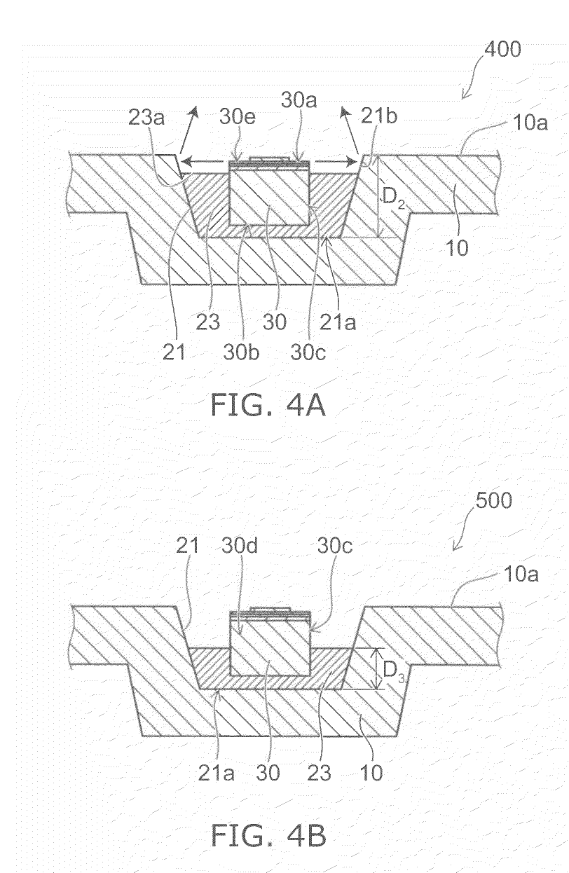

Next, light emitting devices according to other modification examples of the embodiment are described with reference to FIGS. 4A and 4B. FIG. 4A and FIG. 4B are cross-sectional views schematically showing light emitting devices 400 and 500 according to modification examples.

As shown in FIG. 4A, in the light emitting device 400, the depth D₂ of the recess 21 is set deeper than the chip thickness of the light emitting element 30. The light emitting element 30 is fixed to the bottom surface 21a of the recess 21 via the conductive paste 23. The light emitting surface 30a of the light emitting element 30 is inside the recess 21, and is located lower than the front surface 10a of the lead 10.

The front surface 10a of the lead 10 is preferably coated with a metal that reflects the emission light of the light emitting element 30. For example, the front surface 10a is plated with silver (Ag) or gold (Au). Thereby, as indicated by the arrows in FIG. 4A, the light emitted from the light emitting unit 30e in a direction along the surface of the conductive paste 23 is reflected upward (in the direction from the back surface 30b toward the light emitting surface 30a of the light emitting element 30) at the wall surface 21b of the recess 21. Consequently, the luminous flux on the upper side increases, and the light output can be increased.

From this point of view, the recess 21 preferably becomes larger upward. In other words, the opening area of the recess 21 is set larger than the area of the bottom 21b. Thereby, the light emitted from the light emitting element 30 is not blocked by the wall surface 21b of the recess 21. The light reflected at the inclined wall surface 21b is emitted upward with good efficiency. Here, the opening area of the recess 21 refers to the area of the opening along the edge on the opposite side to the bottom surface of the wall surface 21b.

The conductive paste 23 is put in so as to cover the substrate portion of the light emitting element 30, and exposes its surface 23a between the light emitting element 30 and the wall surface of the recess 21.

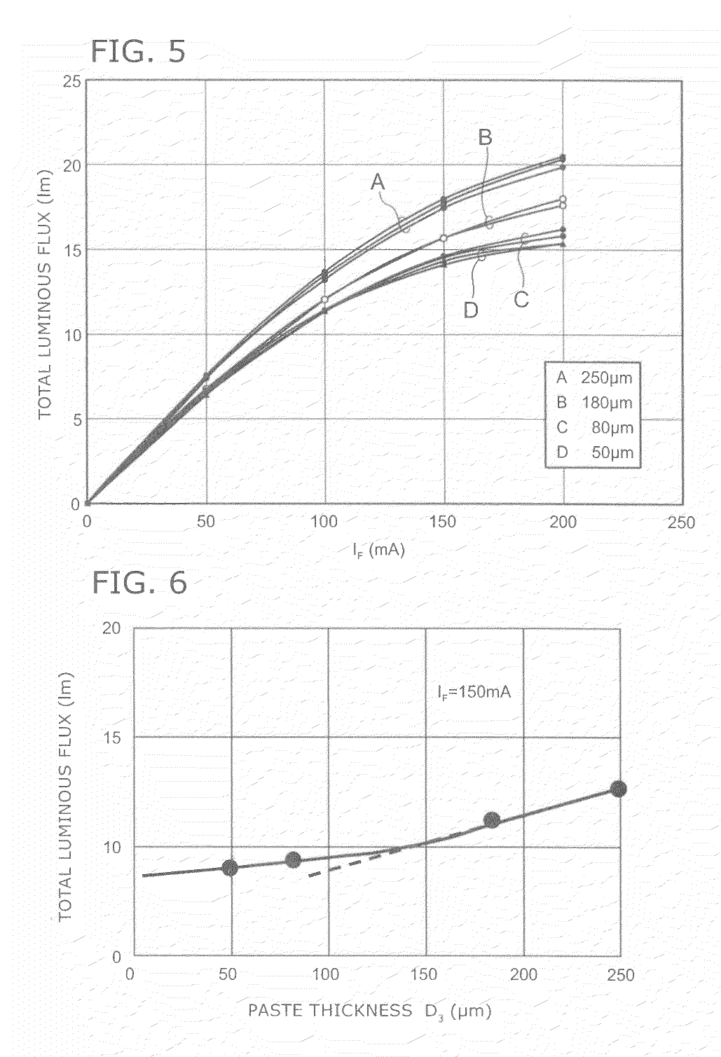

On the other hand, like the light emitting device 500 shown in FIG. 4B, the conductive paste 23 may be provided so as to cover part of the side surface 30c of the light emitting element 30. That is, some degree of effect can be obtained even in a state where part of the substrate 30d of the light emitting element 30 is exposed. For example, FIG. 5 is a graph showing the light output characteristics of the light emitting device 500. The vertical axis represents the total luminous flux outputted from the light emitting device 500, and the horizontal axis represents the drive current I_{F} supplied to the light emitting element 30.

The graph shown in FIG. 5 shows the light output of samples in which the thickness D₃ of the conductive paste 23 is changed between 50 μm and 250 μm with respect to the chip thickness 260 μm of the light emitting element 30. In sample A, D₃=250 μm, and the characteristics of the light emitting device 400 shown in FIG. 4A are shown.

As shown in FIG. 5, as the conductive paste becomes thicker, the total luminous flux increases and the linearity of the total luminous flux to the drive current I_{F} is improved. That is, the light output can be increased by increasing the ratio of the portion covered with the conductive paste 23 of the side surface of the substrate 30d of the light emitting element 30.

Further, FIG. 6 shows the change in the total luminous flux when the drive current I_{F} is set to 150 mA, with respect to the thickness D₃ of the conductive paste 23. As shown in the drawing, it is found that the amount of change depending on the D₃ of the total luminous flux changes near 130 μm and the light output can be further increased when D₃ is set not less than 130 μm. That is, the drawing shows that the thickness D₃ of the conductive paste 23 is preferably set not less than ½ of the chip thickness of the light emitting element 30.

As described above, in the embodiment, the light emitting element 30 is sunk into the conductive paste 23 put in the recess 21 and is fixed to the lead 10. Thus, the side surface 30c of the light emitting element 30 is covered with the conductive paste 23, and the fixing strength and heat radiation of the light emitting element 30 can be increased.

Furthermore, in the side surface 30c of the light emitting element 30, the most part of the substrate 30d is preferably covered with the conductive paste 23. By covering at least a portion more than ½ of the chip thickness of the light emitting element 30, the light output can be effectively increased.

### Second Embodiment

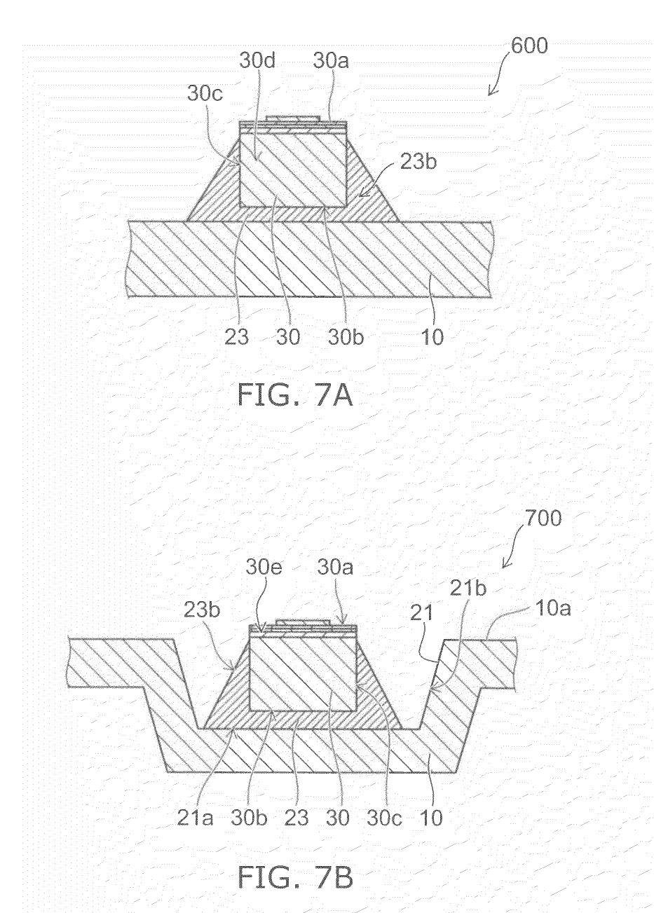

FIGS. 7A and 7B are cross-sectional views schematically showing the mount structures of light emitting elements according to a second embodiment.

In a light emitting device 600 shown in FIG. 7A, the light emitting element 30 is fixed to the front surface 10a of the flat lead 10 via the conductive paste 23. A fillet 23b lying along the outer periphery on the side of the back surface 30b of the light emitting element 30 is provided to cover the side surface 30c. The fillet 23b is part of the conductive paste 23, and preferably covers the most part of the substrate 30d of the light emitting element 30. In the side surface 30c of the light emitting element 30, the fillet 23b is provided so as to cover at least a portion larger than ½ of the chip thickness in the direction from the back surface 30b to the light emitting surface 30a. Thereby, the fixing strength of the light emitting element 30 to the lead 10 and the heat radiation to the lead 10 can be increased.

Like a light emitting device 700 shown in FIG. 7B, the light emitting element 30 may be fixed onto the bottom surface 21a of the recess 21 provided in the lead 10 via the conductive paste 23. In this case, the mount structure of the light emitting device 700 differs from that of the light emitting device 100 shown in FIG. 2B in that the fillet 23b surrounding the outer periphery of the light emitting element 30 is provided.

The fillet 23b preferably covers the most part of the substrate 30d of the light emitting element 30. Furthermore, in the side surface 30c of the light emitting element 30, the fillet 23b is provided so as to cover at least a portion larger than ½ of the chip thickness in the direction from the back surface 30b to the light emitting surface 30a

Thereby, the fixing strength and heat radiation of the light emitting element 30 can be increased. Furthermore, the light output can be increased by coating the front surface 10a of the lead 10 with a metal that reflects the emission light of the light emitting element 30. That is, the light emitted from the light emitting unit 30e in the horizontal direction can be reflected at the wall surface 21b of the recess 21, and the luminous flux traveling from the back surface 30b toward the light emitting surface 30a of the light emitting element 30 can be increased.

### Third Embodiment

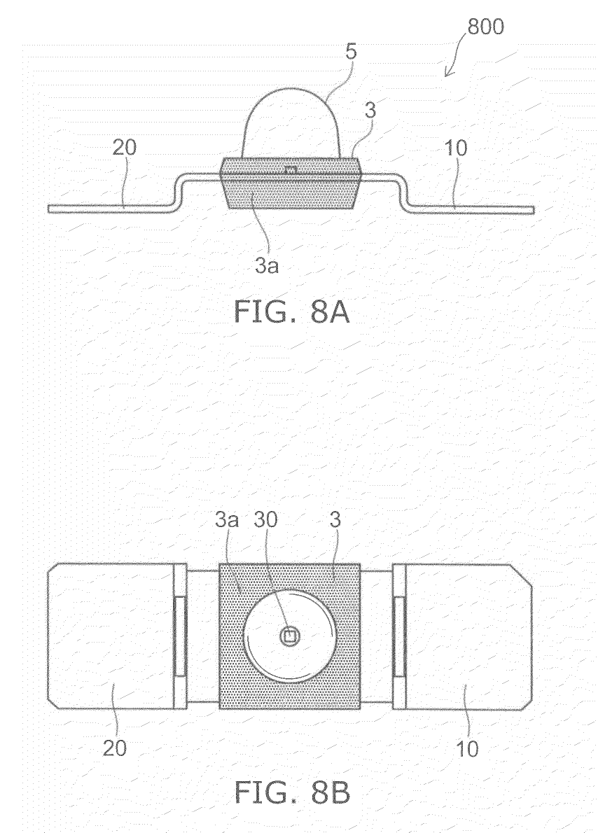

FIGS. 8A and 8B are schematic views showing a light emitting device 800 according to a third embodiment. FIG. 8A is a front view, and FIG. 8B is a plan view.

Also in the light emitting device 800, the light emitting element 30 is fixed to the front surface 10a of the lead 10, and the light emitting element 30 and the lead 20 are electrically connected via the metal wire 19. The light emitting element 30 and the metal wire 19 are resin-sealed by the molded body 3.

The light emitting element 30 is fixed to the lead 10 by means of the mount structure shown in the first embodiment and the second embodiment.

In the embodiment, the surface of the molded body 3 excluding the lens 5 is coated with a light blocking member 3a. The light blocking member 3a is formed so as to cover at least the surface of the molded body 3 on the side where the light emitting element 30 is fixed. Thereby, only the light emitted from the light emitting element 30 via the lens 5 is emitted to the outside. That is, the noise light emitted to the outside of the effective irradiation area is blocked so as not to leak to the outside of the molded body 3.

A material that totally reflects or absorbs noise light is used for the light blocking member 3a. For example, a resin containing fine particles that absorb or reflect the light that the light emitting element 30 emits is applied to or printed on the surface of the molded body 3. Furthermore, a metal film may be formed on the surface of the molded body 3 by vapor deposition.

For example, in the case where a metal film is formed on the surface of the molded body 3, noise light is multiply reflected in the molded body 3, and is emitted to the outside via the lens 5. Therefore, for the light blocking member 3a, using a member that totally reflects light may be more preferable than using a member that absorbs light.

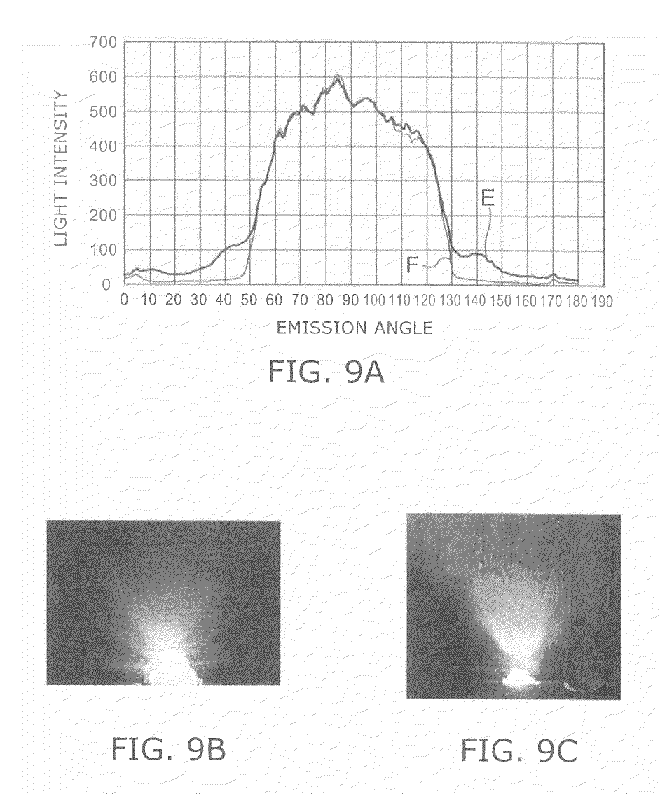

FIGS. 9A to 9C are a graph and photographs showing the light distribution characteristics of the light emitting device 800. FIG. 9A shows the light intensity of the light emitting device 800 with respect to the emission angle. FIG. 9B is a photograph showing the light emitting state of a light emitting device in which the light blocking member 3a is not provided. FIG. 9C is a photograph showing the light emitting state of the light emitting device 800.

In FIGS. 9A to 9C, the intensity of the emitted light is shown with respect to the emission angle from a direction parallel to the front surface of the lead 10. That is, the light intensity at the emission angle of 90 degrees corresponds to the intensity of the light emitted toward the apex of the lens 5.

FIGS. 9A to 9C show the light distribution characteristics of the light emitting device 800 corresponding to graph F and the light distribution characteristics of a light emitting device corresponding to graph E in which the light blocking member 3a is not provided (e.g. the light emitting device 100). In an emission angle range of 90 degrees±40 degrees, since light is emitted via the lens 5, there is no difference between graph E and graph F. On the other hand, in emission angle ranges of not more than 50 degrees and not less than 130 degrees, the light intensity of the light emitting device 800 shown by graph F is suppressed to a low level. In contrast, it is found that, in the light emitting device shown by graph E, light is not suppressed and noise light is included.

As a result of this, in the light emitting state shown in FIG. 9B, the emission of light in the horizontal direction is seen. On the other hand, in the light emitting state of the light emitting device 800 shown in FIG. 9C, the light emission in the horizontal direction is suppressed, and the light emission toward the apex of the lens 5 is relatively strong.

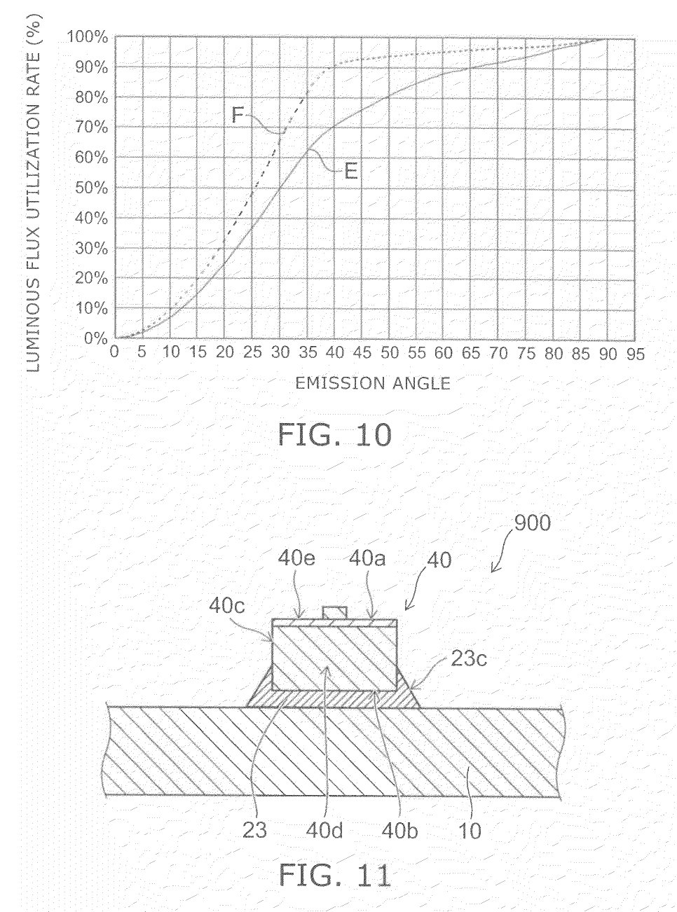

FIG. 10 is a graph showing the luminous flux utilization rates of the light emitting device 800 and a light emitting device according to a comparative example. The vertical axis represents the utilization rate when the light intensity at the emission angle of 90 degrees is taken as a standard, and the horizontal axis represents the emission angle. Herein, the luminous flux utilization rate refers to the proportion of the luminous flux that reaches the light receiving surface out of the total luminous flux.

Graph F shown in FIG. 10 shows the luminous flux utilization rate of the light emitting device 800, and graph E shows the luminous flux utilization rate of a light emitting device in which the light blocking member 3a is not provided. As shown in graph E, in the light emitting device in which the light blocking member 3a is not provided, since noise light is included, the luminous flux utilization rate is low as compared to the light emitting device 800. On the other hand, in the light emitting device 800, as shown in graph F the characteristic that the luminous flux utilization rate is more than 90% is obtained in an effective irradiation area of emission angles of 40 degrees or more.

As described above, the embodiment can suppress noise light, and can provide a light emitting device in which the light/darkness boundary is clear between the effective irradiation area and the other area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light emitting device comprising:
a first lead, a recess being provided in the first lead;
a light emitting element fixed to a bottom surface of the recess via a conductive paste at a back surface on an opposite side to a light emitting surface of the light emitting element; and
a second lead disposed away from the first lead and electrically connected to the light emitting element via a metal wire,
an area of the bottom surface being larger than an area of the light emitting surface,
the paste being put in with a thickness sufficient to cover at least part of a side surface and at least a part of a wall surface of the recess in the recess, the side surface being in contact with the light emitting surface and the back surface of the light emitting element.

2. The device according to claim 1, wherein an opening area of the recess is larger than an area of the bottom surface.

3. The device according to claim 1, wherein the paste is put in thicker than ½ of a thickness of the light emitting element.

4. The device according to claim 1, wherein a depth of the recess is deeper than ½ of a thickness of the light emitting element.

5. The device according to claim 1, wherein a depth of the recess is deeper than a thickness of the light emitting element.

6. The device according to claim 1, wherein the paste contains a metal that reflects light emitted from the light emitting element.

7. The device according to claim 1, wherein the paste has a surface parallel to the bottom surface between the light emitting element and a wall surface of the recess.

8. The device according to claim 1, wherein a front surface of the first lead to which the light emitting element is fixed is coated with a metal that reflects light emitted from the light emitting element.

9. The device according to claim 1, wherein
the light emitting element includes a substrate and a light emitting unit provided on the substrate and
the light emitting unit is protruded from the recess.

10. The device according to claim 1, wherein
the light emitting element includes a substrate and a light emitting unit provided on the substrate,
the substrate absorbs light emitted from the light emitting element, and at least part of a side surface of the substrate is covered with the paste.

11. The device according to claim 1, wherein the light emitting element has unevenness at the side surface thereof.

12. The device according to claim 1, wherein the paste is a silver paste.

13. The device according to claim 1, further comprising a molded body covering the first lead, the second lead, the light emitting element, and the metal wire,
the molded body being configured to transmit light emitted from the light emitting element.

14. The device according to claim 13, wherein
the molded body has an upper surface through which light from the light emitting element is emitted, a lower surface covering a back surface of the first lead on an opposite side to a front surface to which the light emitting element is fixed and a back surface of the second lead on an opposite side to a front surface to which the metal wire is bonded, and a side surface in contact with the upper surface and the lower surface and
the side surface and the lower surface are coated with a member that blocks light from the light emitting element.

15. A light emitting device comprising:
a first lead;
a light emitting element fixed to the first lead; and
a second lead disposed away from the first lead and electrically connected to the light emitting element via a metal wire,
the light emitting element being fixed to the first lead via a conductive paste at a back surface on an opposite side to a light emitting surface, the metal wire being bonded to the light emitting surface,
the paste covering a portion larger than ½ of a thickness of the light emitting element from the back surface of a side surface in contact with the light emitting surface and the back surface of the light emitting element.

16. The device according to claim 15, wherein a fillet made of the paste is provided on the side surface of the light emitting element.

17. The device according to claim 16, wherein the first lead includes a recess to which the light emitting element is fixed and an area of a bottom surface of the recess is larger than an area of a light emitting surface of the light emitting element.

18. The device according to claim 15, wherein a front surface of the first lead to which the light emitting element is fixed is coated with a metal that reflects light emitted from the light emitting element.

19. The device according to claim 15, further comprising a molded body covering the first lead, the second lead, the light emitting element, and the metal wire,
the molded body being configured to transmit light emitted from the light emitting element.

20. The device according to claim 19, wherein
the molded body has an upper surface through which light from the light emitting element is emitted, a lower surface covering a back surface of the first lead on an opposite side to a front surface to which the light emitting element is fixed and a back surface of the second lead on an opposite side to a front surface to which the metal wire is bonded, and a side surface in contact with the upper surface and the lower surface and
the side surface and the lower surface are coated with a member that blocks light from the light emitting element.
